(19) United States
(12) Patent Application Publication
(10) Pub. No.: US 2022/0029719 A1
(43) Pub. Date: Jan. 27, 2022

(54) Simulation Model Fitting for Radio Frequency Matching-Network Optimization

(71) Applicant: Google LLC, Mountain View, CA (US)

(72) Inventors: Hsin-Hung Wu, New Taipei City (TW); Yu-Kai Hung, Taipei (TW); Ting-Yu Guu, Zhubei City (TW)

(73) Assignee: Google LLC, Mountain View, CA (US)

(21) Appl. No.: 16/940,188

(22) Filed: Jul. 27, 2020

(51) Int. Cl. H04B 17/391; H04B 1/04; H03H 7/38

(52) U.S. Cl. CPC H04B 17/3912; H03H 2007/386; H03H 7/38; H04B 1/0458

(57) ABSTRACT

This document describes systems and techniques to perform simulation model fitting for radio frequency (RF) matching-network optimization. Using a simulation tool, a simulation model of the RF interface circuitry is generated with matching component values. Port impedances of the simulation model are adjusted to match at least one or more simulated scattering parameters to at least one or more actual scattering parameter of a physical prototype of the RF interface circuitry assembled with the same matching component values. An optimal load-pull location for the RF interface circuitry is also determined. The simulation model is then used to identify a matching pair that corresponds to the optimal load-pull location. In this way, the described systems and techniques can reduce engineering time and improve the accuracy of the tuning process.

### BACKGROUND

Engineers often perform impedance matching on radio frequency (RF) components and circuit boards during the design and testing process. Impedance matching the output impedance (e.g., a combination of resistance, inductance, or capacitance) of RF circuitry (e.g., an RF interface circuitry between a wireless transceiver and an antenna) can maximize the power transfer and optimize the signal quality of an output signal.

Engineers often perform impedance matching using a blind-tuning process that can take five to seven engineering days to complete for a new RF interface. In this process, engineers choose matching component values, solder the selected component values onto a prototype printed circuit board (PCB), and measure the power transfer and signal quality of the output signal. Many iterations of this process are often required to identify a preferred matching component values, which in some situations may not result in the optimal output impedance. An impedance-matching process that identifies optimal matching component values more accurately and in less time is needed.

### SUMMARY

This document describes systems and techniques to perform simulation model fitting for radio frequency (RF) matching-network optimization. Using a simulation tool, a simulation model of the RF interface circuitry is generated with matching component values. Port impedances of the simulation model are adjusted to match at least one or more simulated scattering parameters to at least one or more actual scattering parameter of a physical prototype of the RF interface circuitry assembled with the same matching component values. An optimal load-pull location for the RF interface circuitry is also determined. The simulation model is then used to identify a matching pair that corresponds to the optimal load-pull location. In this way, the described systems and techniques can reduce engineering time and improve the accuracy of the tuning process.

For example, a method for optimization of a matching-network for RF interface circuitry is described that generates a first instance of a simulation model having first matching component values. The RF interface circuitry includes an antenna port and a front-end module output. The method generates one or more first simulated S-parameter measurements for the first instance of the simulation model with the first matching component values. The method also measures one or more first actual S-parameter measurements from an RF PCB with the RF interface circuitry and the first matching component values. The method adjusts a port impedance of both the antenna port and the front-end module output for the first instance of the simulation model to provide a fitted simulation model. The adjustment of the port impedance is based on differences between the first simulated S-parameter measurements and the first actual S-parameter measurements. Based on at least one signal characteristic, an optimal load-pull location for the RF interface circuitry is determined. The method then uses the fitted simulation model to determine optimized matching component values that correspond to the optimal load-pull location.

This document also describes other methods, and computer-readable storage media including computer-executable instructions, to perform simulation model fitting for RF matching-network optimization.

This summary is provided to introduce simplified concepts for simulation model fitting for RF matching-network optimization, which is further described below in the Detailed Description and Drawings. This summary is not intended to identify essential features of the claimed subject matter, nor is it intended for use in determining the scope of the claimed subject matter.

### BRIEF DESCRIPTION OF THE DRAWINGS

The details of one or more aspects of simulation model fitting for RF matching-network optimization are described in this document with reference to the following drawings. The same numbers are used throughout multiple drawings to reference like features and components:

FIG. 1 illustrates an example environment for simulation model fitting for RF matching-network optimization;

FIG. 2 illustrates example operations performed by a simulation tool to determine optimized matching component values for RF interface circuitry;

FIG. 3 illustrates an RF printed circuit board for which simulation model fitting can be implemented;

FIG. 4 illustrates an example testing setup to obtain load-pull measurements for a device under test;

FIG. 5 is a flowchart illustrating example operations to perform simulation model fitting for RF matching-network optimization;

FIG. 6 is another flowchart illustrating example operations to perform simulation model fitting for RF matching-network optimization; and

FIG. 7 illustrates an example device diagram of a computer system for which simulation model fitting for RF matching-network optimization can be implemented.

### DETAILED DESCRIPTION

### Overview

This document describes simulation model fitting for RF matching-network optimization of RF interface circuitry. The RF interface circuitry can include an RF transceiver (e.g., a Wi-Fi transceiver), a front-end module (FEM), an antenna, and other RF components (e.g., a filter, a coupler, a diplexer).

As described above, engineers often use a blind-tuning process to identify an optimal matching network to maximize power transfer and signal quality output by components of the RF interface circuitry, including the FEM. Blind tuning generally includes a passive-tuning process followed by an active-tuning process.

Passive tuning generally involves soldering one or more pigtails onto a prototype PCB of the RF interface circuitry. Pigtails allow engineers to measure performance characteristics of the RF interface circuitry at points-of-interest, including at the output of the FEM. Engineers can select matching component values (e.g., a resistance value, an impedance value, a capacitance value, or some combination thereof) as a potential matching network and solder them onto the prototype PCB. Engineers can then measure S-parameters of the prototype (e.g., the S₁₁ parameter, which represents the voltage reflection coefficient of the input port) using a network analyzer (e.g., a vector network analyzer (VNA)). Engineers can repeat this process until the S-parameter(s) of interest are sufficiently close to load-pull data provided by a vendor (e.g., the FEM vendor). The vendor load-pull data, however, often does not match measurements obtained from a prototype board. This mismatch can result in a longer passive-tuning process, poor impedance matching, or a combination of both. Many factors, including different operating conditions between the vendor's evaluation board (EVB) and the prototype PCB, components without the same operating characteristics between the EVB and PCB, and improper de-embedding by the vendor can cause this mismatch.

For the active-tuning process, engineers activate the prototype PCB to analyze the performance characteristics of the RF signal. Engineers generally begin by soldering matching component values onto the prototype. The matching-network values are usually the component values identified by passive tuning. Engineers can then measure the transmit power and signal quality (e.g., error vector magnitude (EVM), efficiency) of the RF signal using a signal analyzer (e.g., Litepoint IXcel). This process repeats until engineers identify matching component values that generate optimal transmit power, performance characteristics, or some combination thereof. Although engineers can use simulation to detect general trends in response to different matching component values, the simulations often do not match measurements obtained directly from the prototype PCB. The mismatch between simulation results and actual measurements can force engineers to spend more time actively tuning the prototype to identify the optimal matching component values.

By way of example, blind tuning RF interface circuitry can generally take engineers five to seven days to complete after receiving a prototype PCB. Due to the mismatch between a vendor's load-pull data and measured load-pull data and the mismatch between simulation results and active measurements as described above, blind tuning can also fail to identify the optimal matching network for RF interface circuitry.

In contrast, the described simulation model fitting for RF matching-network optimization can shorten the time and improve the accuracy of impedance matching for RF interface circuitry. First, engineers develop one or more instances of a simulation model of the RF interface circuitry. Simulated S-parameter measurements for the one or more instances of the simulation model can be compared to actual S-parameter measurements from an RF PCB with the RF interface circuitry to adjust a port impedance of the simulation model to generate a fitted simulation model. Engineers can use another instance of the fitted simulation model to validate its accuracy. This process usually requires about a single engineering day, which can begin from design files (e.g., computer-aided design (CAD) files) before the prototype PCB of the RF interface circuitry is received.

Engineers can also obtain load-pull measurements for the prototype of the RF interface. For example, engineers can use an RF tuner to sweep potential load values seen by the FEM of the RF interface circuitry. Based on the load-pull data, engineers can identify the load-pull location associated with optimal transmit power, signal characteristics, or some combination thereof for the prototype PCB.

Lastly, engineers can use the fitted simulation model to identify the matching component values that correspond to the optimal load-pull location. The fitted simulation model saves engineers soldering time and improves the efficiency and accuracy of the tuning process. For example, the described systems and techniques can shorten the tuning process from five to seven days down to one to two days, with a part of this time occurring before a prototype PCB is received.

This example is just one illustration of how the described simulation model fitting for RF matching-network optimization can improve and quicken the impedance matching of RF interface circuitry. Other example configurations and methods are described throughout this document. This document now describes example methods and configurations of the described simulation model fitting for RF matching-network optimization.

### Example Configurations

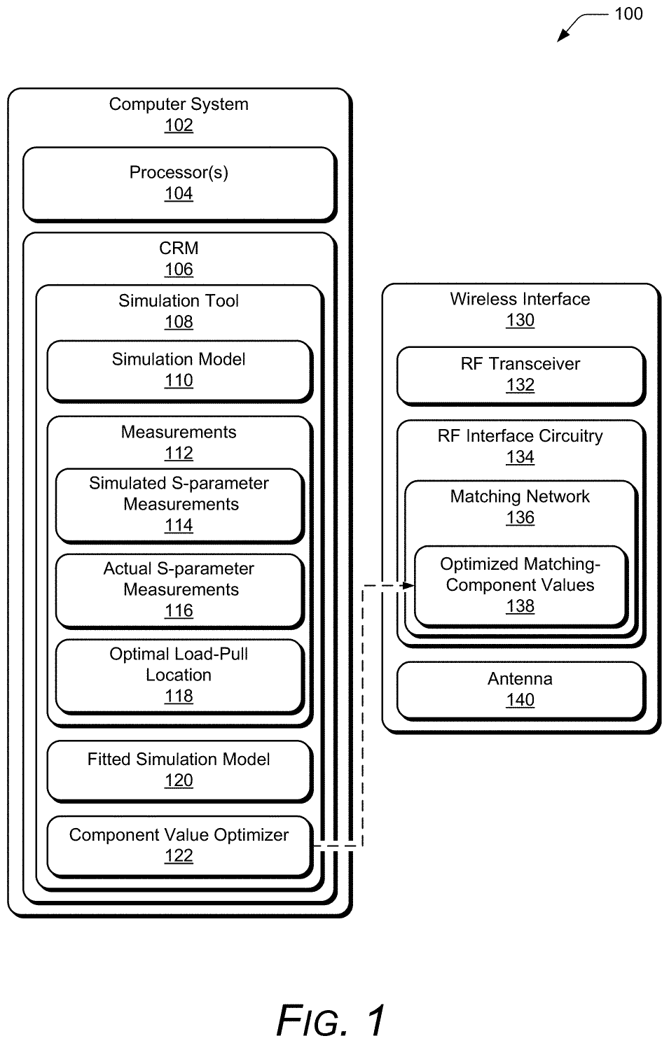

FIG. 1 illustrates an example environment 100 for simulation model fitting for RF matching-network optimization. The environment 100 includes a computer system 102 and a wireless interface 130.

The computer system 102 can be a variety of computing devices used by engineers to perform simulation model fitting for RF matching-network optimization. As non-limiting examples, the computer system 102 can be a mobile phone, a tablet device, a laptop computer, or a desktop computer. The computer system 102 can include one or more processors 104 and computer-readable storage media (CRM) 106. The processor 104 can be a single-core processor or a multiple-core processor. The processor 104 functions as a central processor for the computer system 102. The processor 104 can include other components, such as communication units (e.g., modems), input/output controllers, sensor hubs, system interfaces, and the like.

The CRM 106 includes any suitable storage device (e.g., random-access memory (RAM), static RAM (SRAM), dynamic RAM (DRAM), non-volatile RAM (NVRAM), read-only memory (ROM), Flash memory) to store device data of the computer system 102. The device data can include user data, multimedia data, an operating system, and applications of the computer system 102, which are executable by the processor(s) 104 to enable communications and user interaction with the computer system 102.

For example, the CRM 106 can include a simulation tool 108 to perform simulation model fitting to identify optimized matching-component values 138 for a wireless interface 130. The wireless interface 130 is circuitry for communicating over a wireless network. For example, the wireless interface 130 can be circuitry for an electronic device to communicate over a Wi-Fi network. The wireless interface 130 includes an RF transceiver 132, RF interface circuitry 134, and an antenna 140. The antenna 140 may include an array of multiple antennas, which can be configured similar to or different from each other. The antenna 140 and the RF interface circuitry 134 can be tuned to one or more frequency bands defined by various communication standards and implemented by the RF transceiver 132. The RF interface circuitry 134, which includes at least one matching network 136, can couple or connect the RF transceiver 132 to the antenna 140 to facilitate various types of wireless communications. The matching network 136 can provide resistance, inductance, and capacitance values to maximize power transfer, optimize performance characteristics, or some combination thereof of a signal output by the RF interface circuitry 134.

Engineers can use the simulation tool 108 to determine the optimized matching-component values 138 for the matching network 136 of the RF interface circuitry. The optimized matching-component values 138 can maximize the output power, optimize the error vector magnitude, optimize the performance characteristics, or a combination thereof of a signal output by the RF interface circuitry.

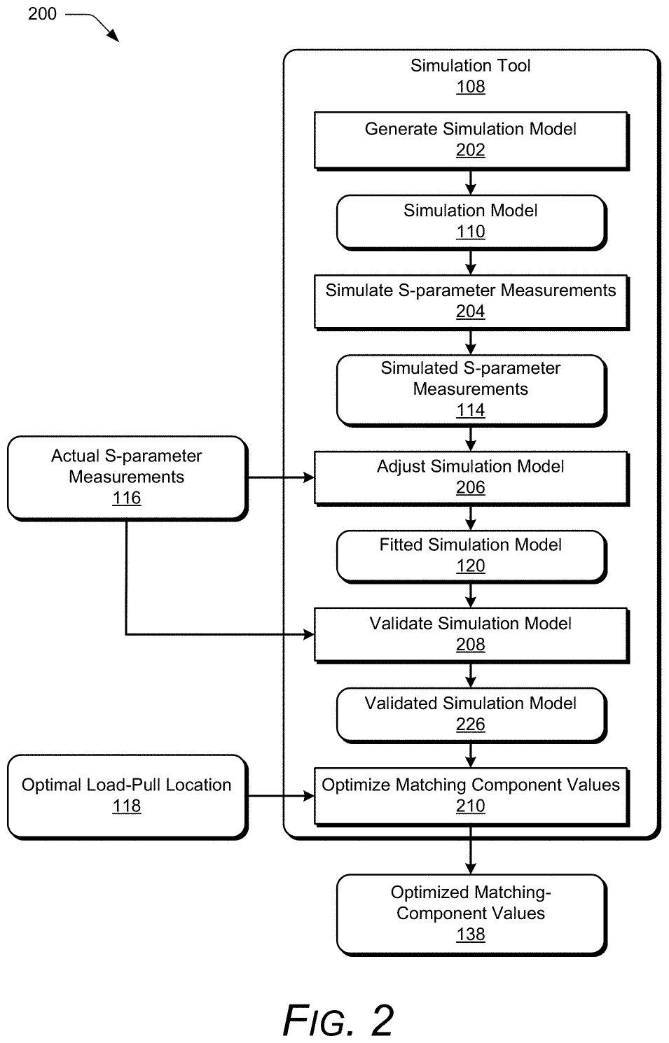

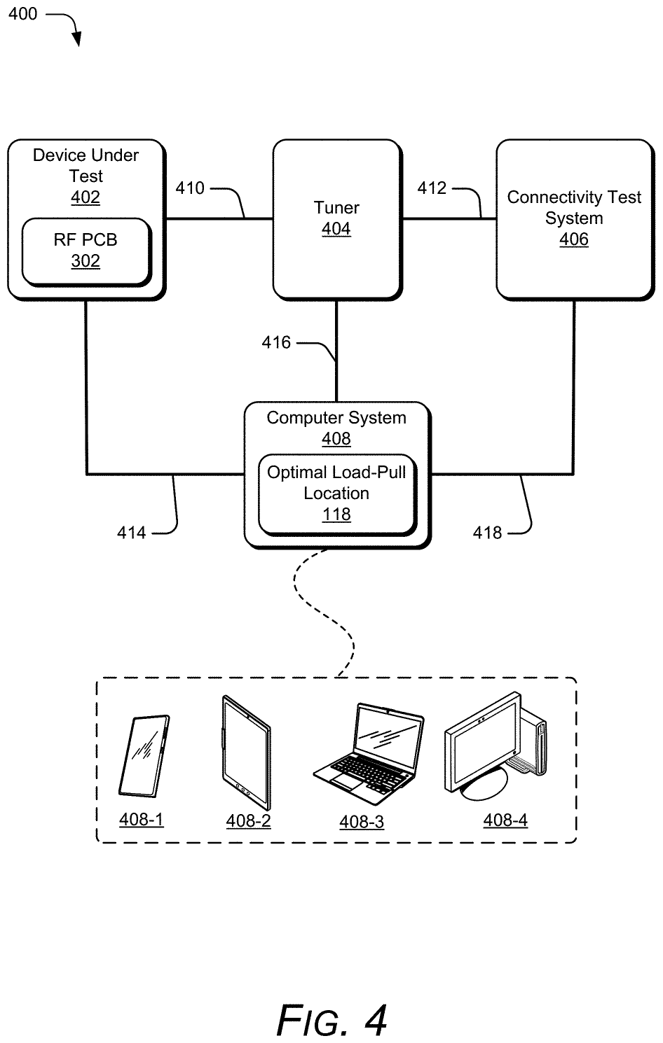

The simulation tool 108 can include a simulation model 110, measurements 112, a fitted simulation model 120, and a component value optimizer 122. The simulation model 110 simulates the physical structure of the RF interface circuitry 134. The simulation tool 108 utilizes measurements 112 to generate a fitted simulation model 120. The measurements 112 can include simulated S-parameter measurements 114, actual S-parameter measurements 116, and an optimal load-pull location 118. The simulated S-parameter measurements 114 are generated by the simulation tool 108 using one or more instance of the simulation model 110 as described in greater detail with respect to FIG. 2. The actual S-parameter measurements 116 are received as inputs to the simulation tool 108 and provide S-parameter measurements from a prototype of RF interface circuitry 134 with a particular matching component values for the matching network 136. The generation of the actual S-parameter measurements 116 are described in greater detail with respect to FIG. 2. The optimal load-pull location 118 is also received as an input to the simulation tool 108. The optimal load-pull location 118, which is described in greater detail with respect to FIG. 4, corresponds to a load point on the RF interface circuitry 134 that results in maximized transmit power, optimized performance characteristics, or some combination thereof.

The component value optimizer 122 utilizes the optimal load-pull location 118 and the fitted simulation model 120 to determine the optimized matching-component values 138 for the RF interface circuitry 134. In this way, the simulation tool 108 allows engineers to accurately and efficiently identify the optimized matching-component values 138 for the RF interface circuitry 134 that result in the desired signal performance.

FIG. 2 illustrates example operations 200 performed by the simulation tool 108 to determine optimized matching-component values 138 for RF interface circuitry 134. The simulation tool 108 may perform operations 200 in a different order or with additional or fewer operations than illustrated.

Engineers can operate the simulation tool 108 on a computer system (e.g., the computer system 102 of FIG. 1) that includes one or more processors and computer-readable storage media. The computer-readable storage media includes memory media and storage media. The processor can execute an operating system and the simulation tool 108 to provide the functionalities described below. The simulation tool 108 can be implemented using hardware, software, firmware, or a combination thereof. For example, the simulation tool 108 can be a high-frequency structure simulator implemented as computer-executable instructions in the computer-readable storage media.

At 202, the simulation tool 108 generates at least two instances of the simulation model 110 (e.g., a first instance and a second instance of the simulation model 110) of the RF interface circuitry 134. The instances of the simulation models 110 simulate the physical structure of the RF interface circuitry 134. The simulation model 110 can be generated in the simulation tool 108 using computer-aided design files of the RF interface circuitry 134. For example, engineers can create the simulation model 110 after the design of the RF interface circuitry 134 is complete, but before receiving one or more prototypes of the RF interface circuitry 134. In this way, engineers can begin the tuning process before receiving the prototypes and shorten the time needed to identify the optimized matching-component values 138 for the RF interface circuitry 134. As another example, engineers can use the simulation tool 108 to generate the instances of the simulation model 110 from structures and components included in the simulation tool 108 to simulate the physical structure of the RF interface circuitry 134.

The instances of the simulation model 110 include different matching component values for the matching network 136. For example, the first instance of the simulation model 110 has first matching-network component values, and the second instance of the simulation model 110 has second matching-network component values. The matching network 136 can include multiple combinations of matching pairs or a single set of matching pairs. The matching network 136 can include capacitive values, inductive values, resistance values, or a combination thereof.

At 204, engineers or the simulation tool 108 adjusts port impedances of the instances of the simulation model 110. The simulation tool 108 simulates the emission of an RF signal by the instances of the simulation model 110 and measures at least one simulated S-parameter (e.g., the S₁₁ parameter) for each instance of the simulation model 110. The simulation tool 108 compares the simulated S-parameter measurements 114 to the actual S-parameter measurements 116, which engineers can input to the simulation tool 108.

The actual S-parameter measurements 116 include at least one scattering parameter measured from the prototype of the RF interface circuitry 134. Engineers can measure the S-parameters using a vector network analyzer. For example, engineers modify one or more prototypes of the RF interface circuitry 134 to include the first matching-network component values and the second matching component values. Engineers can solder inductors and capacitors onto one or more prototypes of the RF interface circuitry 134 to obtain the inductance and capacitance values of the first matching-network component values and the second matching-network component values.

Engineers or the simulation tool 108 adjust the port impedances of the simulation model 110 until the simulated S-parameter measurements 114 match the actual S-parameter measurements 116. For example, engineers, using the simulation tool 108, can adjust the port impedances of the simulation model 110 until the simulated S-parameter measurements 114 visually match the actual S-parameter measurements 116. The simulation tool 108 can provide a Smith chart representation of the simulated S-parameter measurements 114 and the actual S-parameter measurements 116 to assist engineers in identifying the port impedance of the simulation model 110. Alternatively, the simulation tool 108 can automate the adjustments and iteratively adjust the port impedance of the simulation model 110 until the simulated S-parameter measurements 114 match the actual S-parameter measurements 116. The port impedances of the simulation model 110 are generally the same for each instance of the simulation model 110. Once the port impedances of the simulation model 110 are adjusted, the simulation tool 108 generates a fitted simulation model 120 of the RF interface circuitry 134.

At 206, the simulation tool 108, based on actual S-parameter measurements 116, validates the fitted simulation model 120 and outputs a validated simulation model 226. The actual S-parameter measurements 116 are received as inputs to the simulation tool 400. These actual S-parameter measurements 116 include at least one S-parameter measured from the prototype of the RF interface circuitry 134 with other matching-network component values. For example, engineers can set up the prototype of the RF interface circuitry 134 to have third matching-network component values. Engineers can then measure the at least one actual S-parameter measurements 116 and provide the results to the simulation tool 108. In this way, the simulation tool 108 can verify that the fitted simulation model 120 can accurately predict the matching component values of the matching network 136 for the RF interface circuitry 134.

At 208, the simulation tool 108, based on an optimal load-pull location 118 of the RF interface circuitry 134, identifies the optimized matching component values 138. Engineers can input the optimal load-pull location 118 to the simulation tool 108. As described below with respect to FIG. 4, the optimal load-pull location 118 can represent a load seen by the RF interface circuitry 134 that maximizes power transfer, minimizes the error vector magnitude, or some combination thereof for the output signal.

The simulation tool 108 adjusts the matching component values of the matching network 136 of the validated simulation model 226 to correspond to the optimal load-pull location 118. In this way, the simulation tool 108 can determine the optimized matching-component values 138 via simulation. The simulation tool 108 allows engineers to identify the optimized matching-component values 138 via simulations and avoids the need to solder and measure a series of different matching component values. The simulation tool 108 also allows engineers to precisely and accurately predict the optimized matching-component values 138 that correspond to the optimal load-pull location 118.

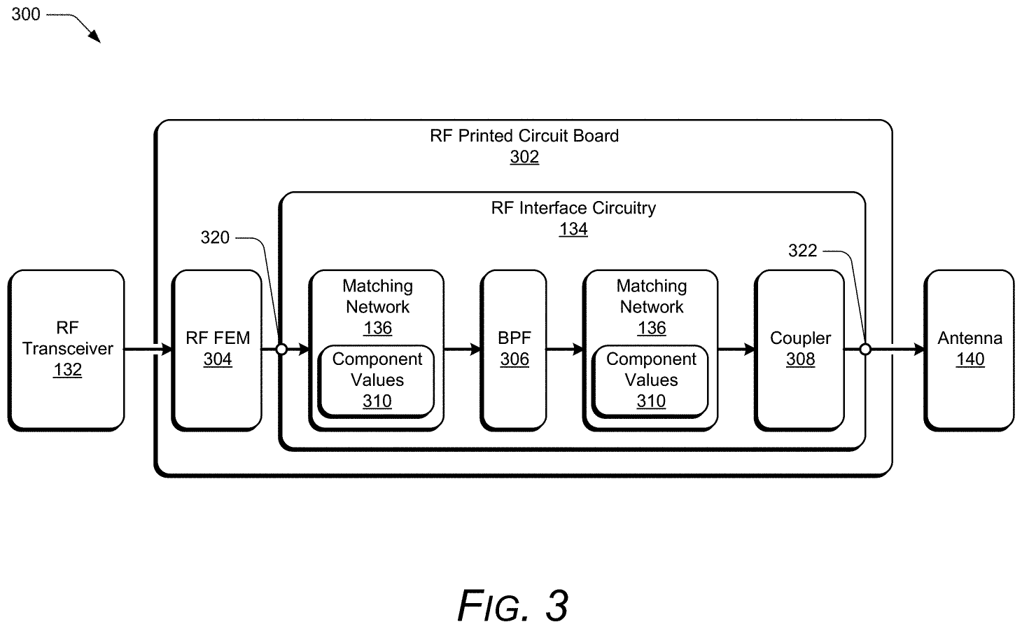

FIG. 3 illustrates an example device diagram 300 of an RF printed circuit board (PCB) 302 for which simulation model fitting can be implemented. The RF PCB 302 can be a prototype of the wireless interface 130 or at least a portion of the wireless interface 130. The RF PCB 302 can include an RF front end module (FEM) 304 and the RF interface circuitry 134. The RF PCB 302 can be connected to the RF transceiver 132 and the antenna 140. The RF PCB 302 can include a subset of the components illustrated in FIG. 3 or additional components.

The RF FEM 304 can be a single module (e.g., an integrated circuit) that includes several components. Alternatively, the RF FEM 304 can be a collection of circuitry on the RF PCB 302. The RF FEM 304 can include a power amplifier, a low noise amplifier, and a switch. The RF FEM 304 is connected to the RF transceiver(s) 132 and processes the transmit signal and outputs it at a FEM output (FEMout) port 320.

The RF interface circuitry 134 can include one or more matching networks 136, a bandpass filter (BPF) 306, and a coupler 308. The one or more matching networks 136 can include resistance, inductance, capacitance, or any combination thereof. The matching networks 136 include component values 310, which represent values of the resistance, inductance, or capacitance elements. Engineers can select the component values 310 of the matching networks 136 to maximize power transfer, optimize performance characteristics, or some combination thereof of a signal from a source to a load.

The BPF 306 passes frequencies of the signal within a particular range and rejects frequencies outside of this range. The coupler 308 couples a specific amount of power in the transmission line of the RF interface circuitry 134 to an antenna port 322. As described above, the antenna 140 transmits and receives RF signals.

Load-pull measurements can be performed on the RF PCB 302 to identify the output impedance seen by the RF FEM 304 that maximizes the transmit power, optimizes a performance characteristic, or a combination thereof at the FEMout port 320. Systems and techniques to perform load-pull measurements and identify an optimal load-pull location 118 are described in greater detail with respect to FIG. 4.

FIG. 4 illustrates an example testing setup 400 to obtain load-pull measurements for a device under test 402, which is a product or prototype undergoing testing and analysis. For example, the device under test 402 can include a prototype of the RF PCB 302. The testing setup 400 also includes a tuner 404, a connectivity test system 406, and a computer system 408.

The device under test 402 connects to the tuner 404 via a connector 410. The connector 410 can include a trace, a pigtail, an RF cable, or any combination thereof. The tuner 404 generates a series of potential loads on a port of the device under test 402. For example, engineers can connect the tuner 404 to the FEMout port 320 of the RF PCB 302.

Before beginning the load-pull measurements, engineers can calibrate the tuner 404. For the calibration, engineers can program the tuner 404 to sweep between a start frequency and a stop frequency at particular frequency intervals. The start frequency, the stop frequency, and the frequency interval can be set based on the type of RF signals to be transmitted or received by the device under test 402. For example, if the device under test 402 is the RF PCB 302 for a Wi-Fi transceiver, then the start frequency can be 2 GHz, the stop frequency can be 6 GHz, and the frequency interval can be 1 MHz, which results in 4001 sweep points for the calibration process.

The connectivity test system 406 connects to the tuner 404 via a connector 412. The connector 412 can be an RF cable. The connectivity test system 406 can measure transmit power values and signal characteristics (e.g., error vector magnitude, efficiency, harmonics) for the device under test 402. As an example, the connectivity test system 406 can be an IQxel™ test system from LitePoint.

The computer system 408 can control operations of the tuner 404 and receive measurement values from the connectivity test system 406. The computer system 408 connects to the tuner 404 via a connector 416. The computer system 408 also connects to the connectivity test system 406 via a connector 418. The connectors 416 and 418 can be an ethernet cable or similar connector (e.g., universal serial bus (USB) connector) that transmits data between the computer system 408 and the tuner 404 and the connectivity test system 406, respectively.

The computer system 408 connects to the device under test 402 via a connector 414. The connector 414 can be a USB connector or similar connector (e.g., ethernet cable) that transmits data between the computer system 408 and the device under test 402. In other implementations, the connectors 414, 416, and 418 can be a wireless connection, including communications over a wireless local access network (WLAN).

The computer system 408 can be a variety of computing devices used by engineers to test and analyze the performance of the device under test 402. As non-limiting examples, the computer system 408 can be a mobile phone 408-1, a tablet device 408-2, a laptop computer 408-3, or a desktop computer 408-4.

The computer system 408 can include one or more processors, a graphical user interface (GUI), and computer-readable storage media (CRM). The one or more processors can be single-core processors or multiple-core processors. The GUI can be an interactive display that conveys information (e.g., test results) and represents actions taken by an engineer (e.g., an input to the computer system 408 made by the engineer through a mouse, a keyboard, or a touchscreen). For example, the GUI can be used to control the tuner 404 or the connectivity test system 406 and analyze the collected measurement data.

The CRM can include any suitable storage device, including random-access memory (RAM), static RAM (SRAM), dynamic RAM (DRAM), non-volatile RAM (NVRAM), read-only memory (ROM), or Flash memory. The CRM stores a suite of modules and computer-executable instructions that, when executed by the one or more processors, direct the computer system 408 to perform operations to obtain load-pull measurements for the device under test 402 and identify the optimal load-pull location 118.

In operation, engineers program the tuner 404 to sweep possible loads seen at the FEMout port 320 of the RF PCB 302. The connectivity test system 406 measures the transmit power, performance characteristics, or a combination thereof of the output signal for the different load points. The computer system 408 can plot the measurement values obtained by the connectivity test system 406 on a Smith chart for each of the transmit power and performance characteristics measured. Based on the measurement values or the Smith chart(s), engineers can identify the optimal load-pull location 118 for the FEMout port 320 of the RF PCB 302.

For example, the optimal load-pull location 118 can correspond to the highest transmit power, the smallest EVM, or a balancing point between the highest transmit power and the smallest EVM. The described systems and techniques use the optimal load-pull location 118 to determine the optimal matching pair for the RF PCB 302, which is described in greater detail with respect to FIG. 4.

### Example Methods

This section illustrates example methods of simulation model fitting for RF matching-network optimization, which may include fewer or additional operations. This section describes various example methods, each described in relation to a specific drawing for ease of reading.

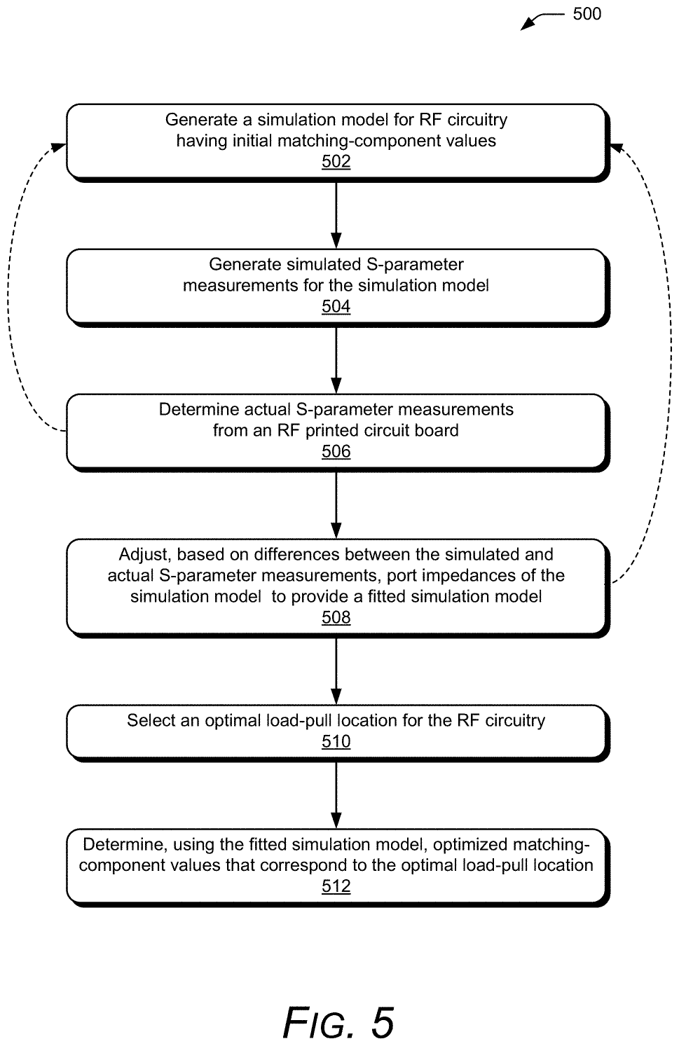

FIG. 5 is a flowchart illustrating example operations 500 performed for simulation model fitting for RF matching-network optimization. The operations 500 are described in the context of the simulation tool 108 of FIGS. 1 and 2. The operations 500 may be performed in a different order or with additional or fewer operations than illustrated.

At 502, a simulation model for RF circuitry having initial matching component values is generated. The RF circuitry includes a first port and a second port. For example, engineers can use the simulation tool 108 to generate the simulation model 110 of RF interface circuitry 134 having initial matching component values for a matching network 136. The RF interface circuitry 134 includes a first port and a second port (e.g., the FEMout port 320 and the antenna port 322).

At 504, one or more simulated S-parameter measurements for the simulation model are generated based on the initial matching component values. For example, the simulation tool 108 can generate simulated S-parameter measurements 114 for the simulation model 110 having the initial matching component values.

At 506, one or more first actual S-parameter measurements are determined from an RF PCB on which the RF circuitry is embodied with the initial matching component values. For example, engineers measure actual S-parameter measurements 116 from the RF PCB 302 on which the RF interface circuitry 134 is embodied having the initial matching component values. As described above, engineers can solder the initial matching component values onto the RF PCB 302 and use a VNA to measure the actual S-parameter measurements 116. The actual S-parameter measurements 116 can then be loaded into or input to the simulation tool 108.

In some instances, engineers repeat operations 502 through 506 to generate another instance of the simulation model 110 with other matching component values. The simulation tool 108 then generates other simulation S-parameter measurements 114 and receives as inputs other actual S-parameter measurements 116 for the other matching component values.

At 508, a port impedance of at least one of the first port or the second port of the simulation model is adjusted to provide a fitted simulation model for the RF circuitry. The adjustment is based on differences between the simulated S-parameter measurements and the actual S-parameter measurements. For example, the simulation tool 108 can adjust the port impedance of at least one of the FEMout port 320 or the antenna port 322 of the simulation model 110 to provide the fitted simulation model 120. The simulation tool 108 can set the default port impedance for the FEMout port 320 and the antenna port 322 as 50 ohms. The adjustment of the port impedance is based on differences between the simulated S-parameter measurements 114 and the actual S-parameter measurements 116. As an example, the simulation tool 108 can adjust the port impedance to match the simulated S-parameter measurements 114 to the actual S-parameter measurements 116. As the port impedance is adjusted, the simulation tool 108 generates the simulated S-parameter measurements 114 again until there is a sufficient match between the simulated S-parameter measurements 114 and the actual S-parameter measurements 116. In some instances, the simulation tool 108 repeats operations 502 through 508 to validate the fitted simulation model 120.

In instances where operations 502 through 506 are repeated to generate the other instance of the simulation model 110, operation 508 is performed based on differences between the simulated S-parameter measurements 114 and the actual S-parameter measurements 116 for the respective instances of the simulation model 110.

At 510, an optimal load-pull location is selected for one of the first port or the second port of the RF circuitry based on a measured load-pull location of an RF component to which the first port or the second port will be operably connected. For example, engineers can use the testing setup 400 to select the optimal load-pull location 118 for the RF interface circuitry 134. The optimal load-pull location 118 can be selected based on a measured load-pull location of an RF component (e.g., the RF FEM 304) to which the second port (e.g., the FEMout port 320) will be operably coupled. For example, the optimal load-pull location can be selected based on at least one signal characteristic, including power transfer, error vector magnitude, and efficiency, of the output signal from the RF FEM 304.

At 512, optimized matching component values for the matching network of the RF circuitry that correspond to the optimal load-pull location for the first port or the second port are determined using the fitted simulation model. For example, the simulation tool 108, using the fitted simulation model 120 or the validated simulation model 226, can identify the optimized matching-component values 138 of the matching network 136 that correspond to the optimal load-pull location 118. The optimized matching-component values 138 can be effective to operate the RF FEM 304 with a maximum power transfer, a minimized error vector magnitude, a maximized efficiency, or some combination thereof.

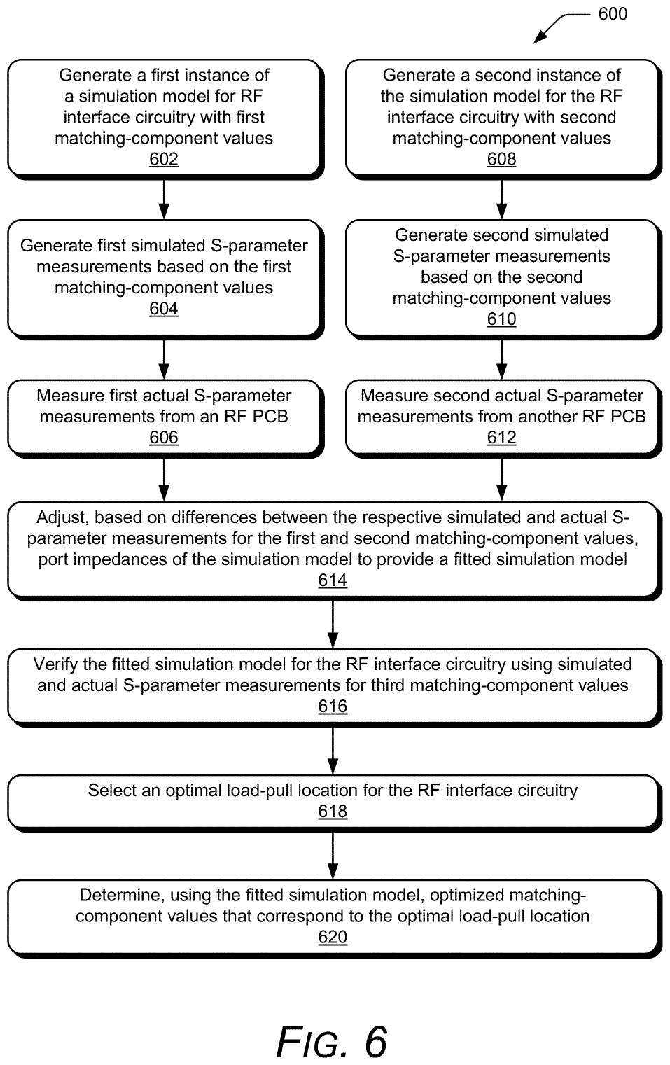

FIG. 6 is another flowchart illustrating example operations 600 performed for simulation model fitting for RF matching-network optimization. The operations 600 are described in the context of the simulation tool 108 of FIGS. 1 and 2. The operations 600 may be performed in a different order or with additional or fewer operations than illustrated.

At 602, a first instance of a simulation model for RF interface circuitry having first matching component values is generated. The RF interface circuitry includes an antenna port and a front-end module output. For example, engineers can use the simulation tool 108 to generate a first instance of the first simulation model 110 of RF interface circuitry 134 having first matching component values for a matching network 136. The RF interface circuitry 134 includes the FEMout port 320 and the antenna port 322.

At 604, one or more first simulated S-parameter measurements, based on the first matching component values, are generated for the first instance of the simulation model. For example, the simulation tool 108 can generate, based on the first matching component values, simulated S-parameter measurements 114 for the first instance of the simulation model 110.

At 606, one or more first actual S-parameter measurements from an RF PCB on which the RF interface circuitry is embodied with the first matching component values are measured. For example, engineers measure actual S-parameter measurements 116 from the RF PCB 302 on which the RF interface circuitry 134 is embodied with the first matching component values. As described above, engineers can solder the first matching component values into the RF PCB 302 and use a VNA to measure the actual S-parameter measurements 116. The actual S-parameter measurements 116 can then be loaded into or input to the simulation tool 108.

At 608, a second instance of the simulation model for RF interface circuitry having second matching component values is generated. The second matching component values are different than the first matching component values. For example, engineers can use the simulation tool 108 to generate a second instance of the first simulation model 110 of RF interface circuitry 134 having second matching component values for a matching network 136. The second matching component values are different than the first matching component values.

At 610, one or more second simulated S-parameter measurements, based on the second matching component values, are generated for the second instance of the simulation model. For example, the simulation tool 108 can generate, based on the second matching component values, simulated S-parameter measurements 114 for the second instance of the simulation model 110.

At 612, one or more second actual S-parameter measurements from another RF PCB on which the RF interface circuitry is embodied with the second matching component values are measured. For example, engineers measure actual S-parameter measurements 116 from another RF PCB 302 on which the RF interface circuitry 134 is embodied with the second matching component values. As described above, engineers can solder the second matching component values into the other RF PCB 302 and use a VNA to measure the actual S-parameter measurements 116. The actual S-parameter measurements 116 can then be loaded into or input to the simulation tool 108. The operations 608 through 612 can be performed concurrent with or after the operations 602 through 606.

At 614, a port impedance of at least one of the antenna port or the front-end module output for the simulation model are adjusted to provide a fitted simulation model for the RF interface circuitry. The adjustment of the port impedance is based on differences between the first and second simulated S-parameter measurements and the first and second actual S-parameter measurements, respectively. For example, the simulation tool 108 can adjust the port impedance of at least one of the FEMout port 320 or the antenna port 322 of the simulation model 110 to provide the fitted simulation model 120. The adjustment of the port impedance is based on differences between the first and second simulated S-parameter measurements 114 and the first and second actual S-parameter measurements 116, respectively. As an example, the simulation tool 108 can adjust the port impedance to match the first and second simulated S-parameter measurements 114 to the first and second actual S-parameter measurements 116, respectively. As the port impedance is adjusted, the simulation tool 108 generates the first and second simulated S-parameter measurements 114 again until there is a sufficient match between the first and second simulated S-parameter measurements 114 and the first and second actual S-parameter measurements 116, respectively.

At 616, the fitted simulation model for the RF interface circuitry is verified using third simulated and actual S-parameter measurements for third matching component values. For example, the simulation tool 108 verifies the fitted simulation model 120. The simulation tool 108 generates a third instance of the fitted simulation model 120 with third matching component values. The third matching component values are different than the first matching component values and the second matching component values. The simulation tool 108 generates third simulated S-parameter measurements 114 for the third instance of the fitted simulation model 120. The simulation tool 108 also receives third actual S-parameter measurements 116 from the RF PCB 302 with the third matching component values. The simulation tool 108 then confirms that the fitted simulation model 120 provides a sufficient match between the third simulated S-parameter measurements 114 and the third actual S-parameter measurements 116 to provide the validated simulation model 226.

At 618, an optimal load-pull location for the RF interface circuitry is selected for one of the antenna port or the FEMout port of the RF circuitry based on a measured load-pull location of an RF component to which the antenna port or the FEMout port will be operably connected. For example, engineers can use the testing setup 400 to select the optimal load-pull location 118 for the RF interface circuitry 134. The optimal load-pull location 118 can be selected based on a measured load-pull location of the RF FEM 304 to which the FEMout port 320 will be operably coupled. As an example, the optimal load-pull location can be selected based on at least one signal characteristic, including power transfer, error vector magnitude, and efficiency, of the output signal from the RF FEM 304.

At 620, optimized matching component values for the matching component of the RF interface circuitry that corresponds to the optimal load-pull location for the antenna port or the FEMout port are determined using the fitted simulation model. For example, the simulation tool 108, using the fitted simulation model 120 or the validated simulation model 226, can identify the optimized matching-component values 138 of the matching network 136 that correspond to the optimal load-pull location 118. The optimized matching-component values 138 can be effective to operate the RF FEM 304 with a maximum power transfer, a minimized error vector magnitude, a maximized efficiency, or some combination thereof.

### Example Device Implementation

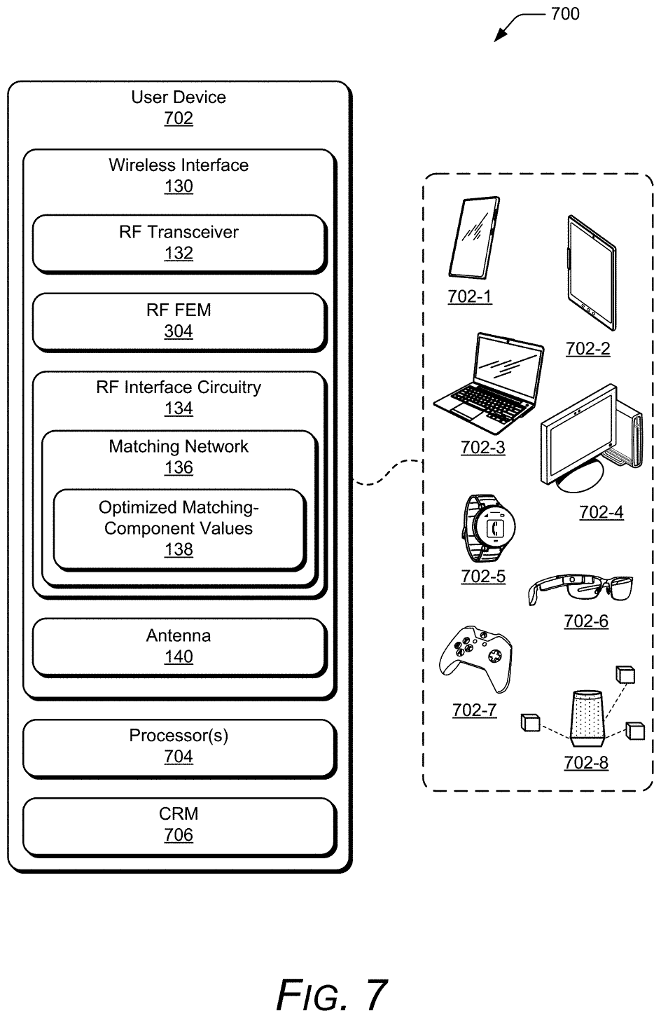

FIG. 7 illustrates an example device diagram 700 of a user device 702 for which simulation model fitting for RF matching-network optimization can be implemented. The user device 702 may include additional functions and interfaces omitted from FIG. 7 for the sake of clarity.

The user device 702 can be a variety of consumer electronic devices. As non-limiting examples, the user device 702 can be a mobile phone 702-1, a tablet device 702-2, a laptop computer 702-3, a desktop computer 702-4, a computerized watch 702-5, a wearable computer 702-6, a video game controller 702-7, or a voice-assistant system 702-8.

The user device 702 includes one or more wireless interfaces 130, one or more processors 704, and CRM 706. In this example, the user device 702 includes the wireless interface 130 and the same components therein to those shown for the wireless interface 130 in FIG. 1. In particular, the wireless interface 130 includes an RF transceiver 132, an RF FEM 304, RF interface circuitry 134, and an antenna 140 for communicating over wireless networks. The RF FEM 304 and the RF interface circuitry 134 can couple or connect the RF transceiver 132 to the antenna 104 to facilitate various types of wireless communications. The antenna 140 of the user device 702 may include an array of multiple antennas, which can be configured similar to or different from each other. The antenna 140, the RF interface circuitry 134, and the RF FEM 304 can be tuned to one or more frequency bands defined by various communication standards and implemented by the RF transceiver 132.

The RF interface circuitry 134 includes one or more matching networks 136, which include optimized matching component values 138. As described above, simulation model fitting is performed to identify the optimized matching-component values 138 for the matching network 136. As described above, the optimized component values 138 can maximize the output power, optimize the error vector magnitude, optimize the performance characteristics, or a combination thereof of a signal output by the RF FEM 304.

The processor 704 can be a single-core processor or a multiple-core processor. The processor 704 functions as a central processor for the user device 702. The processor 704 can include other components, such as communication units (e.g., modems), input/output controllers, sensor hubs, system interfaces, and the like.

The CRM 706 includes any suitable storage device (e.g., random-access memory (RAM), static RAM (SRAM), dynamic RAM (DRAM), non-volatile RAM (NVRAM), read-only memory (ROM), Flash memory) to store device data of the user device 702. The device data can include user data, multimedia data, an operating system, and applications of the user device 702, which are executable by the processor 704 to enable communications and user interaction with the user device 702.

### Conclusion

While various configurations and methods for simulation model fitting for RF matching-network optimization have been described in language specific to features and/or methods, it is to be understood that the subject of the appended claims is not necessarily limited to the specific features or methods described. Rather, the specific features and methods are disclosed as non-limiting examples of simulation model fitting for RF matching-network optimization.

What is claimed is:

1. A method for optimization of a matching network of radio frequency (RF) circuitry, the method comprising:
generating a simulation model for the RF circuitry, the RF circuitry having a first port and a second port, the simulation model having initial matching component values;
generating, based on the initial matching component values, one or more simulated scattering parameter (S-parameter) measurements for the simulation model;
determining one or more actual S-parameter measurements from an RF printed circuit board on which the RF circuitry is embodied with the initial matching component values;
adjusting, based on differences between the simulated S-parameter measurements and the actual S-parameter measurements, a port impedance of at least one of the first port or the second port of the simulation model, the adjusting to provide a fitted simulation model for the RF circuitry;
selecting an optimal load-pull location for one of the first port or the second port of the RF circuitry based on a measured load-pull location of an RF component to which the first port or the second port will be operably coupled; and
determining, using the fitted simulation model, optimized matching component values for the matching network of the RF circuitry that correspond to the optimal load-pull location for the first port or the second port.

2. The method of claim 1, wherein:
the initial matching component values are first matching component values, the simulation model is a first instance of the simulation model having the first matching component values, the one or more simulated S-parameter measurements are first simulated S-parameter measurements, and the actual S-parameter measurements are first actual S-parameter measurements; and
the method further comprises:
generating a second instance of the simulation model for the RF circuitry having second matching component values, the second matching component values different than the first matching component values;
generating, based on the second matching component values, one or more second simulated S-parameter measurements for the second instance of the simulation model; and
determining one or more second actual S-parameter measurements from another RF printed circuit board on which the RF circuitry is embodied with the second matching component values, and
wherein adjusting the port impedance comprises adjusting, based on differences between respective simulated S-parameter measurements and actual S-parameter measurements for the first matching component values and the second matching component values, the port impedance of at least one of the first port or the second port of the simulation model of the RF circuitry, the adjusting to provide the fitted simulation model.

3. The method of claim 2, the method further comprising:
generating a third instance of the simulation model for the RF circuitry having third matching component values, the third matching component values different than the first matching component values and the second matching component values;
generating, based on the third matching component values, one or more third simulated S-parameter measurements for the third instance of the simulation model;
determining one or more third actual S-parameter measurements from a third RF printed circuit board on which the RF circuitry is embodied with the third matching component values; and
verifying, based on a comparison between the third simulated S-parameter measurements and the third actual S-parameter measurements, the fitted simulation model for the RF circuitry.

4. The method of claim 1, wherein an initial port impedance of the first port and the second port is 50 ohms.

5. The method of claim 1, wherein the first port is an antenna port and the second port is an output of a front-end module.

6. The method of claim 2, wherein the adjusted port impedance of the first port and the second port of both the first instance and the second instance of the simulation model are the same values.

7. The method of claim 1, wherein selecting the optimal load-pull location for one of the first port or the second port of the RF circuitry comprises:
sweeping, using a RF tuner, load values at the first port or the second port of the RF printed circuit board on which the RF circuitry is embodied; and
identifying, for each of the load values, a signal characteristic of an output signal.

8. The method of claim 7, wherein the signal characteristic includes at least one of a transmit power, an error vector magnitude, or an efficiency of the output signal.

9. The method of claim 1, wherein the initial matching component values include one or more of a capacitive value, an inductive value, or a resistance value.

10. The method of claim 1, wherein the simulation model and the fitted simulation model are generated using computer-aided design files of the RF circuitry.

11. The method of claim 1, wherein the generation of the one or more simulated S-parameter measurements for the simulation model is performed using an RF simulator software or an advanced design system software; and the method further comprises:
receiving, into the RF simulator software or the advanced design system software, the one or more actual S-parameter measurements.

12. The method of claim 1, wherein the RF circuitry is RF interface circuitry between an antenna and an RF transceiver.

13. A computer-readable storage media comprising computer-executable instructions for optimization of a matching network of radio frequency (RF) circuitry, the computer-executable instructions, when executed, cause one or more processors of a computer system to:
generate a simulation model for the RF circuitry, the RF circuitry having a first port and a second port, the simulation model having initial matching component values;
generate, based on the initial matching component values, one or more simulated scattering parameter (S-parameter) measurements for the simulation model;
receive one or more actual S-parameter measurements, the actual S-parameter measurements determined from an RF printed circuit board on which the RF circuitry is embodied with the initial matching component values;
adjust, based on differences between the simulated S-parameter measurements and the actual S-parameter measurements, a port impedance of at least one of the first port or the second port of the simulation model, the adjustment to provide a fitted simulation model for the RF circuitry; and
determine, using the fitted simulation model, optimized matching component values for the matching network of the RF circuitry that correspond to an optimal load-pull location for the first port or the second port, the optimal load-pull location based on a measured load-pull location of an RF component to which the first port or the second port will be operably coupled.

14. The computer-readable storage media of claim 13, wherein:
the initial matching component values are first matching component values, the simulation model is a first instance of the simulation model having the first matching component values, the one or more simulated S-parameter measurements are first simulated S-parameter measurements, and the actual S-parameter measurements are first actual S-parameter measurements; and
the computer-readable storage media comprising computer-executable instructions, which when executed, further cause the one or more processors of the computer system to:
generate a second instance of the simulation model for the RF circuitry having second matching component values, the second matching component values different than the first matching component values;
generate, based on the second matching component values, one or more second simulated S-parameter measurements for the second instance of the simulation model; and
receive one or more second actual S-parameter measurements, the second actual S-parameter measurements determined from another RF printed circuit board on which the RF circuitry is embodied with the second matching component values, and
wherein adjustment of the port impedance comprises adjust, based on differences between respective simulated S-parameter measurements and actual S-parameter measurements for the first matching component values and the second matching component values, the port impedance of at least one of the first port or the second port of the simulation model of the RF circuitry, the adjustment to provide the fitted simulation model.

15. The computer-readable storage media of claim 14, the computer-readable storage media comprising computer-executable instructions, which when executed, further cause the one or more processors of the computer system to:
generate a third instance of the simulation model for the RF circuitry having third matching component values, the third matching component values different than the first matching component values and the second matching component values;
generate, based on the third matching component values, one or more third simulated S-parameter measurements for the third instance of the simulation model;
receive one or more third actual S-parameter measurements, the third actual S-parameter measurements determined from a third RF printed circuit board on which the RF circuitry is embodied with the third matching component values; and
verify, based on a comparison between the third simulated S-parameter measurements and the third actual S-parameter measurements, the fitted simulation model for the RF circuitry.

16. The computer-readable storage media of claim 13, wherein the first port is an antenna port and the second port is an output of a front-end module.

17. The computer-readable storage media of claim 14, wherein the adjusted port impedance of the first port and the second port of both the first instance and the second instance of the simulation model are the same values.

18. A method for optimization of a matching network of radio frequency (RF) interface circuitry, the method comprising:
generating a simulation model for the RF interface circuitry, the RF interface circuitry having an antenna port and a front-end module (FEM) output, the simulation model having initial matching component values;
generating, based on the initial matching component values, one or more simulated scattering parameter (S-parameter) measurements for the simulation model;
receiving one or more actual S-parameter measurements, the actual S-parameter measurements determined from an RF printed circuit board on which the RF circuitry is embodied with the initial matching component values;
adjusting, based on differences between the simulated S-parameter measurements and the actual S-parameter measurements, a port impedance of at least one of the antenna port or the FEM output of the simulation model, the adjusting to provide a fitted simulation model for the RF circuitry;
determining, using the fitted simulation model, optimized matching component values for the matching network of the RF circuitry that correspond to an optimal load-pull location for the antenna port or the FEM output, the optimal load-pull location based on a measured load-pull location of an RF component to which the antenna port or the FEM output will be operably coupled.

19. The method of claim 18, the method further comprising:
the initial matching component values are first matching component values, the simulation model is a first instance of the simulation model having the first matching component values, the one or more simulated S-parameter measurements are first simulated S-parameter measurements, and the actual S-parameter measurements are first actual S-parameter measurements; and
the method further comprises:
generating a second instance of the simulation model for the RF circuitry having second matching component values, the second matching component values different than the first matching component values;
generating, based on the second matching component values, one or more second simulated S-parameter measurements for the second instance of the simulation model; and
receiving one or more second actual S-parameter measurements, the second actual S-parameter measurements determined from another RF printed circuit board on which the RF circuitry is embodied with the second matching component values, and
wherein adjusting the port impedance comprises adjusting, based on differences between respective simulated S-parameter measurements and actual S-parameter measurements for the first matching component values and the second matching component values, the port impedance of at least one of the antenna port or the FEM output of the simulation model of the RF circuitry, the adjustment to provide the fitted simulation model.

20. The method of claim 19, the method further comprising:
generating a third instance of the simulation model for the RF circuitry having third matching component values, the third matching component values different than the first matching component values and the second matching component values;
generating, based on the third matching component values, one or more third simulated S-parameter measurements for the third instance of the simulation model;
receiving one or more third actual S-parameter measurements, the third actual S-parameter measurements determined from a third RF printed circuit board on which the RF circuitry is embodied with the third matching component values; and
verifying, based on a comparison between the third simulated S-parameter measurements and the third actual S-parameter measurements, the fitted simulation model for the RF circuitry.
